(19) United States
(12) Patent Application Publication
(10) Pub. No.: US 2023/0088909 A1
(43) Pub. Date: Mar. 23, 2023

(54) DUAL CONDUCTION THERMAL SOLUTION

(71) Applicant: Benjamin K. Sharfi, Rancho Cucamonga, CA (US)

(72) Inventor: Benjamin K. Sharfi, Rancho Cucamonga, CA (US)

(21) Appl. No.: 17/934,094

(22) Filed: Sep. 21, 2022

Related U.S. Application Data
(60) Provisional application No. 63/246,509, filed on Sep. 21, 2021.

(51) Int. Cl. H05K 7/20; G06F 1/20

(52) U.S. Cl. CPC H05K 7/20309; H05K 7/20409; G06F 1/20

(57) ABSTRACT

Disclosed is thermal management device that combines a vapor chamber with a mechanical heat sink to provide improved cooling performance under extreme conditions—the vapor chamber and heat sink combination comprises a single-unit device where the vapor chamber side of the device is in direct contact with the heat source and the opposite side of the vapor chamber is equipped with cooling fins that mate with cooperatively sized fins on the heat sink portion of the device.

### CLAIM OF PRIORITY

This application is being filed as a non-provisional patent application under 35 U.S.C. § 111(a) and 37 CFR § 1.53(b). This application claims priority under 35 U.S.C. § 119(e) to U.S. provisional patent application Ser. No. 63/246,509 filed on Sep. 21, 2021, the contents of which are incorporated herein by reference.

### FIELD OF INVENTION

The present invention relates to cooling solutions for electronic devices. More specifically, the present invention relates to methods and systems for the dissipation of heat from electronic components such as central processor units (CPUs) and graphic processor units (GPUs).

### SUMMARY OF THE INVENTION

Disclosed is thermal management device that combines a vapor chamber with a mechanical heat sink to provide improved cooling performance under extreme conditions. The vapor chamber and heat sink combination comprises a single-unit device. The vapor chamber side of the device is in direct contact with the heat source. The opposite side of the vapor chamber is equipped with cooling fins that mate with cooperatively sized fins on the heat sink portion of the device.

### BRIEF DESCRIPTION OF THE DRAWINGS

FIG. 1 shows the top and bottom orthogonal views of a vapor chamber assembly in accordance with the present invention.

FIG. 2 shows the top and bottom orthogonal views of a heat sink assembly in accordance with the present invention.

FIG. 3 shows an orthogonal exploded views of a combination vapor chamber/heat sink assembly in accordance with the present invention.

FIG. 4 shows Thermal simulation of disclosed cooling system. Colors indicate temperature gradient of the cold plate when subjected to 500 W heat power at 25° C. ambient.

### DETAILED DESCRIPTION OF THE INVENTION

Following are detailed descriptions of several aspects of the present invention, all of which relate to a thermal management device that combines a vapor chamber with a mechanical heat sink to provide improved cooling performance under extreme conditions.

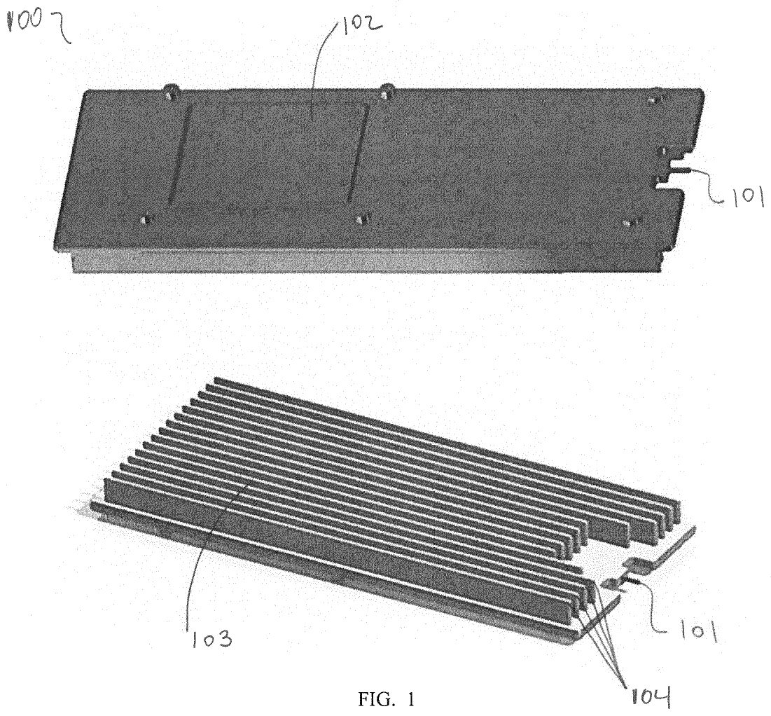

As shown in FIG. 1, the vapor chamber assembly (100) comprises a substantially flat hollow cavity which is filled with a working fluid substantially comprising ethanol, methanol, deionized water, and combinations thereof. The working fluid is inserted through a filler tube (101) on the side wall. The interior of the vapor chamber assembly is at least partially lined with a sintered wick layer. The wick layer may be made of copper or similar conducting metal, optionally applied as a powder coating to maximize surface area. The vapor chamber assembly (100) has a component contacting side (102) and an opposite side (103) through which heat is dissipated. The component contacting (102) side is either substantially flat or has a surface which closely matches a component to be cooled. The opposite side has a plurality of fins (104). The thermal contact between the component to be cooled and the component-contacting side (102) of the vapor chamber assembly (100) is maximized by using low resistance thermal grease liquefied diamond coolant compounds. The material of the vapor chamber assembly (100) may be copper, stainless steel, or nickel.

As heat is absorbed by the vapor chamber assembly (100) through the component contacting side (102), the component contacting side (102) is cooled. Heat is transferred to the working fluid which evaporates and, in turn, transfers heat to the plurality of fins (104) on the opposite side, reversing phase again into liquid form. Using this design, the vapor chamber temperature range is very high, up to 150° C., due to its distinctive cavity and wick design whereas typical vapor chamber temperatures are around 100° C.

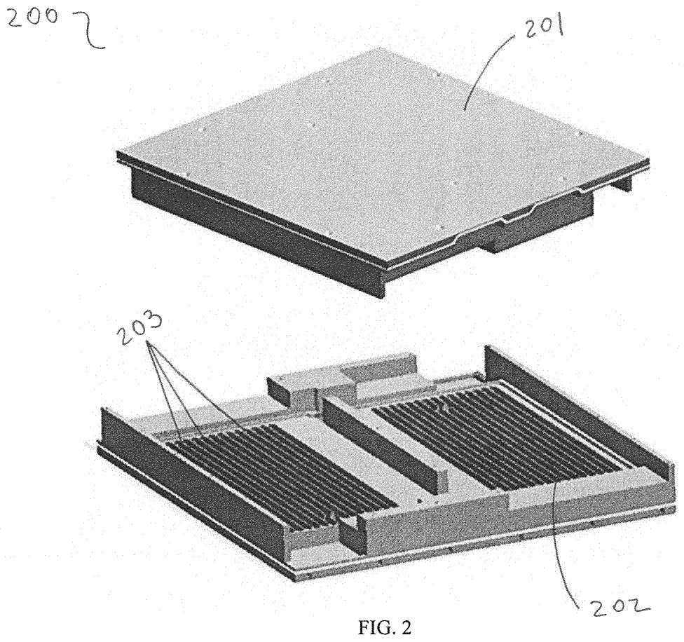

As shown in FIG. 2, the heat sink assembly (200) comprises a substantially solid plate having a heat dissipating side (201) and an opposite side (202) with a plurality of fins (203). The plurality of fins (203) are sized to cooperatively engage the plurality of fins (104) on the vapor chamber assembly and substantially eliminate any air gaps between the two assemblies. The heat sink assembly (200) is adapted to absorb heat through its plurality of fins (203) from the plurality of fins (104) on the vapor chamber assembly (100), and then dissipate the heat through the heat sink assembly's (200) opposite side (202)

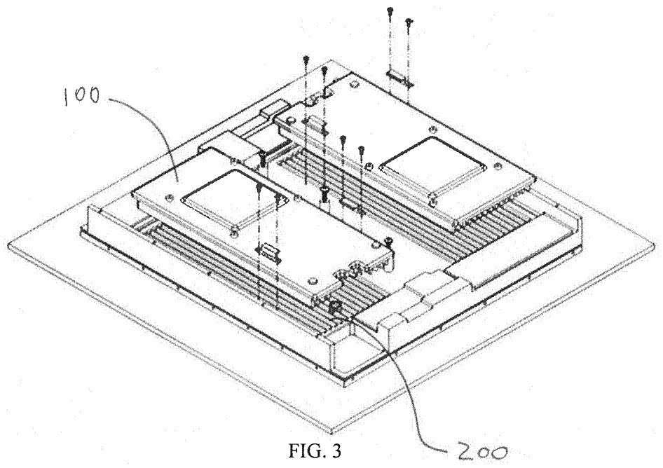

As shown in FIG. 3, the heat sink (200) and vapor chamber (100) are assembled by mating the two sets of plurality of fins (104, 203) into a unitary component. The fit between the two components may be a “snap” or a press fit. The fins are optionally anodized for electrical insulation, corrosion resistance, hardness, and heat absorption enhancement.

Additional characteristics of the assembly components device are as follows: i) screws posts stand-offs around the vapor chamber plate provide mechanical contact between the conduction plate and the electronic devices such as video processors GPU or CPU, ii) stand offs cantilever by the vapor inlet filler tube which provides stability, iii) compression springs on the base plate provide protection from mechanical shock and vibration, iv) conductive elastomer electromagnetic interference (EMI) gaskets provide moisture and pressure sealing system for the vapor chamber, v) a single heat sink can receive multiple vapor chambers depending on thermal load to be cooled.

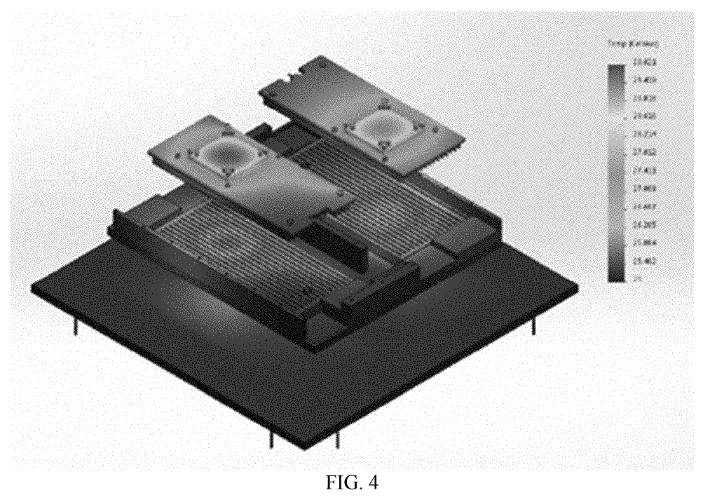

FIG. 4 provides a simulated example of the cooling performance of a thermal management device in accordance with the present disclosure. In most conditions the use of the disclosed cooling solution can enable a completely fan-less system. The scalable design of the disclosed cooling solution enables the use of 2, 3, 4 or more high-performance CPUs and/or GPUs side by side without thermal issues.

Although described above in connection with particular hardware configurations and standards, these descriptions are not intended to be limiting as various modifications may be made therein without departing from the spirit of the invention and within the scope and range of equivalent of the described embodiments. Encompassed embodiments of the present invention can be used in all applications where electronic equipment of any nature needs to be cooled.

We claim:

1. A thermal management device comprising:
a vapor chamber assembly having a component contacting side and an opposite side, the component contacting side adapted for contacting a component to be cooled, the opposite side comprising a plurality of fins;
a heat sink assembly having a heat dissipating side and an opposite side, the heat dissipating side adapted for dissipating heat entering the heat sink, the opposite side comprising a plurality of fins;
wherein the plurality of fins in the opposite side of the vapor chamber assembly and the plurality of fins in the opposite side of the heat sink assembly are sized to cooperatively engage and substantially eliminate any air gaps between them upon mating.

2. The thermal management device of claim 1 wherein the vapor chamber assembly and the heat sink assembly are press fit.

3. The thermal management device of claim 1 wherein the vapor chamber assembly comprises a sintered wick layer.

4. The thermal management device of claim 1 wherein the vapor chamber assembly comprises ethanol, methanol, deionized water, or combinations thereof.
